(19) United States
(12) Patent Application Publication
(10) Pub. No.: US 2011/0024178 A1
(43) Pub. Date: Feb. 3, 2011

(54) SUBSTRATE OF A WIRING BOARD AND A DRILLING METHOD THEREOF

(76) Inventor: Tingjui CHEN, Taoyuan County (TW)

Correspondence Address: Muncy, Geissler, Olds & Lowe, PLLC, 4000 Legato Road, Suite 310, FAIRFAX, VA, 22033, US

(21) Appl. No.: 12/579,861

(22) Filed: Oct. 15, 2009

(30) Foreign Application Priority Data
Jul. 30, 2009 (TW) 098125693

(51) Int. Cl. H05K 1/11; B23K 26/38

(52) U.S. Cl. 174/262; 219/121.71

(57) ABSTRACT

A substrate of a wiring board is provided with at least one through-hole and includes an upper conductive layer, a lower conductive layer and an insulation layer. The lower conductive layer is opposite to the upper layer and the insulation layer is configured between the upper conductive layer and the lower conductive layer. The through-hole is formed by penetrating the upper conductive layer, the insulation layer and the lower conductive layer and is provided with a wall at the insulation layer, with a surface roughness of the wall being within 10 microns.

### CROSS-REFERENCE TO RELATED APPLICATION

This application claims the benefit of Taiwan Patent Application No. 098125693, filed on Jul. 30, 2009, which is hereby incorporated by reference for all purposes as if fully set forth herein.

### BACKGROUND OF THE INVENTION

1. Field of the Invention

The present invention relates to a wiring board and a manufacturing method thereof, and more particularly to a substrate of a wiring board and a drilling method thereof.

2. Related Art

In manufacturing a wiring board, a drilling procedure will be normally carried out to form plural through-holes in a board material of the wiring board, wherein this board material is like a substrate of copper foil or a resin layer on which a metal layer has been deposited.

In general, the aforementioned drilling procedure will usually employ a mechanical drilling method and all ordinary through-hole drilling procedures will use a mechanical drill. In other words, the through-holes on an existing wiring board are generally formed by the mechanical drilling method.

### SUMMARY OF THE INVENTION

The present invention provides a substrate of a wiring board, which at least one through-hole is provided in the substrate of the wiring board.

The present invention provides a drilling method for a substrate of a wiring board, in order to form the through-hole in the substrate of the wiring board.

In one embodiment of the present invention, a substrate of a wiring board is provided with at least one through-hole and comprises an upper conductive layer, a lower conductive layer which is opposite to the upper conductive layer, and an insulation layer which is configured between the upper conductive layer and the lower conductive layer, wherein the through-hole is formed by penetrating the upper conductive layer, the insulation layer and the lower conductive layer and is formed with a wall at the insulation layer, with a surface roughness of the wall being within 10 microns.

In one embodiment of the present invention, through-hole is formed by ablation with a laser beam.

In one embodiment of the present invention, an aperture of the through-hole is below 75 microns.

In one embodiment of the present invention, the insulation layer is a prepreg.

In one embodiment of the present invention, the insulation layer includes plural threads of a fiber material.

In one embodiment of the present invention, the fiber materials are provided respectively with plural fused ends which are exposed on the wall, with the fused ends of one thread of the fiber material being welded with the fused ends of another thread of the fiber material.

In one embodiment of the present invention, the fiber materials are fiber glass.

In one embodiment of the present invention, the insulation layer further includes an adhesive material which encloses the fiber materials.

In one embodiment of the present invention, the adhesive material is resin.

In one embodiment of the present invention, the through-hole is further provided with a top opening at the upper conductive layer and a bottom opening at the lower conductive layer, with the top opening being overlapped with the bottom opening.

In one embodiment of the present invention, a difference between an aperture of the top opening and an aperture of the bottom opening is within 10 microns.

In one embodiment of the present invention, a drilling method for a substrate of a wiring board comprises providing a laser drill table which includes a desk plate and a laser generator, with the laser generator emitting a laser beam toward the desk plate, configuring a laser absorption plate on the desk plate, configuring a board material on the laser absorption plate, and irradiating the laser beam on the board material to form in the board material at least one through-hole.

In one embodiment of the present invention, an absorption rate of the laser absorption plate to light with a wavelength between 200 nm and 14000 nm is larger than 80%.

In one embodiment of the present invention, the laser absorption plate is made by polymethylmethacrylate, epoxy resin, polytetrafluoroethylene, wood, pulp or ceramic.

In one embodiment of the present invention, before configuring the board material on the laser absorption plate, the drilling method further includes forming a laser absorption film layer on the board material, such that when the board material is configured on the laser absorption plate, the laser absorption film layer is located between the board material and the laser absorption plate.

In one embodiment of the present invention, the method for forming the laser absorption film layer includes attaching a dry film on the board material.

In one embodiment of the present invention, the laser generator is a carbon dioxide laser device, an ultraviolet laser device or an excimer laser apparatus.

In one embodiment of the present invention, upon configuring the board material on the laser absorption plate, the laser drill table adsorbs the board material from the desk plate.

In one embodiment of the present invention, the desk plate is provided with plural vacuum absorption holes and the laser absorption plate is provided with plural perforations which are connected with the vacuum absorption holes.

In one embodiment of the present invention, the desk plate includes a first metal plate and a second metal plate which is configured on the first metal plate.

The present invention utilizes a laser beam to ablate a board material, forming at least one through-hole on the board material, so as to constitute a substrate of a wiring board having at least one through-hole.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1A shows a cutaway view of a substrate of a wiring board of an embodiment of the present invention.

FIG. 1B shows a local exploded view at a through-hole of the substrate of the wiring board in FIG. 1A.

FIGS. 2A to 2C show flow diagrams of a drilling method for the substrate of the wiring board, as shown in FIG. 1A.

FIGS. 3A and 3B show flow diagrams of a drilling method for a substrate of a wiring board, according to an embodiment of the present invention.

### DETAILED DESCRIPTION OF THE PREFERRED EMBODIMENTS

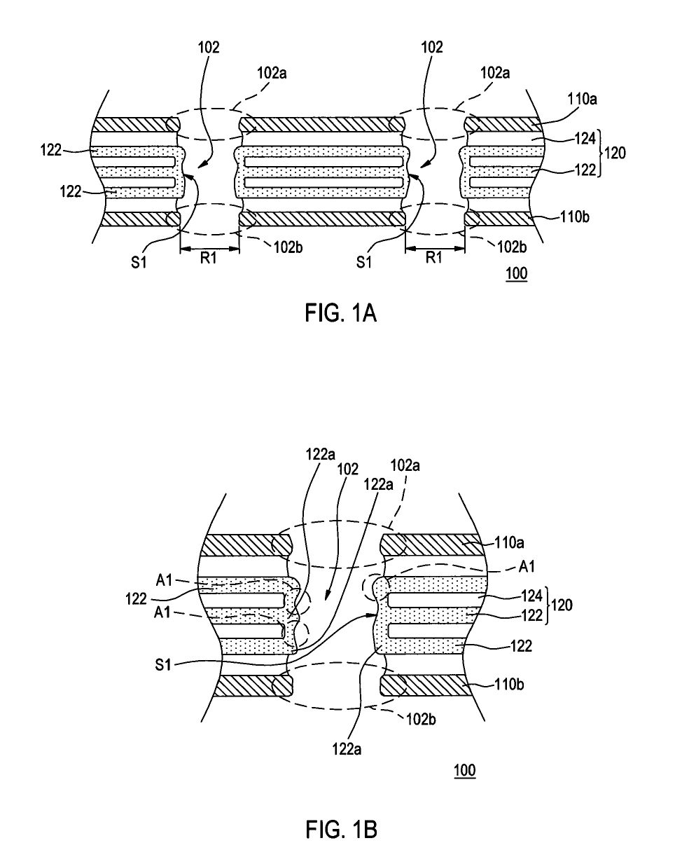

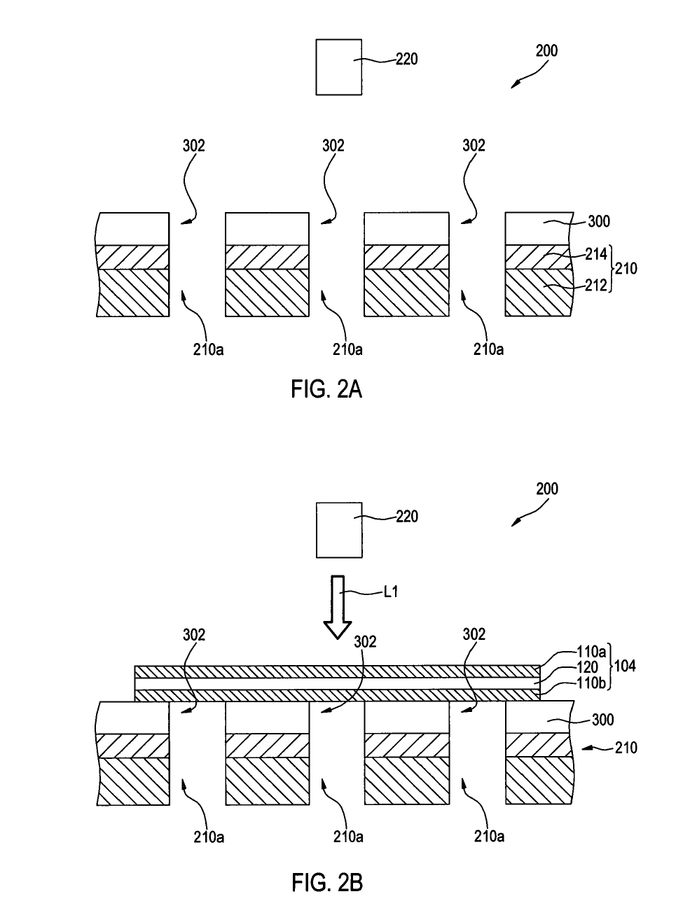

Referring to FIG. 1A, it shows a cutaway view of a substrate of a wiring board of an embodiment of the present invention. As shown in FIG. 1A, a substrate 100 of a wiring board comprises an upper conductive layer 110a, a lower conductive layer 110b and an insulation layer 120. The insulation layer 120 is configured between the upper conductive layer 110a and the lower conductive layer 110b, and the lower conductive layer 110b is opposite to the upper conductive layer 110a. In other words, the upper conductive layer 110a and the lower conductive layer 110b are configured respectively at two opposite sides of the insulation layer 120.

Accordingly, the substrate 100 of the wiring board is provided with at least one through-hole 102. For example, in the embodiment shown in FIG. 1A, the substrate 100 of the wiring board is provided with plural through-holes 102. However, in other embodiments which are not shown in the drawing, the substrate 100 of the wiring board can have only one through-hole 102. These through-holes 102 are formed by penetrating the upper conductive layer 110a, the insulation layer 120 and the lower conductive layer 110b. That is to say, these through-holes 102 are extended from the upper conductive layer 110a, through the insulation layer 120, to the lower conductive layer 110b.

The through-holes 102 can be made into a conductive through-hole structure or a conductive buried-hole structure; while the substrate 100 of the wiring board can be made directly into a double-sided wiring board or can be made into a circuit layer in a multi-layered wiring board. For example, by using a build-up method, the substrate 100 of the wiring board is made into a core circuit layer in the multi-layered wiring board. In other embodiments which are not shown in the drawing, the substrate 100 of the wiring board can further include a metallic core layer in the insulation layer 120.

Referring to FIG. 1B, it shows a local exploded view at a through-hole of the substrate of the wiring board in FIG. 1A. As shown in FIG. 1A and FIG. 1B, each through-hole 102 is provided with a wall S1 at the insulation layer 120 and the wall S1 is also a surface of the insulation layer 120 at the through-hole 102. In these through-holes 102, a surface roughness of the wall S1 is within 10 microns.

The aforementioned surface roughness refers to a difference between a maximum height and a minimum height in a single local area A1 of the wall S1 or can be an averaged difference between a maximum height and a minimum height in plural local areas A1 or a difference between a maximum height and a minimum height in all areas of the wall S1 for a same through-hole 102. Therefore, in each local area A1 or all areas of the wall S1, the difference between the maximum height and the minimum height is about within 10 microns.

When the surface roughness of the wall S1 is within 10 microns, a subsequent PTH (Plated Through Hole) procedure will be facilitated, allowing a metallic plating material (not shown in the drawings) to be easily deposited on these walls S1, thereby successfully forming a metallic layer (not shown in the drawings) on the wall S1.

On the other hand, the surface roughness of the wall S1 can be also larger than 5 microns and between 5 microns and 10 microns. When the surface roughness of the wall S1 is above 5 microns, an adhesion force of the metallic layer formed by the PTH procedure to the wall S1 can be increased. Thus, the metallic layer will not be scaled off from the wall S1 easily.

The through-holes 102 can be formed by ablation with a laser beam and an aperture R1 of these through-holes 102 can be below 75 microns, wherein the aperture R1 refers to an averaged aperture of a single through-hole 102 and the laser beam can be provided by a carbon dioxide laser device, an ultraviolet laser device or an excimer laser apparatus. As a result, a wavelength of the laser beam can be between 200 nm and 14000 nm and a range of this wavelength is equivalent to a wavelength of far infrared light to a wavelength of near ultraviolet light.

Each through-hole 102 is further provided with a top opening 102a and a bottom opening 102b. The top opening 102a is located at the upper conductive layer 110a and the bottom opening 102b is located at the lower conductive layer 110b, wherein the top opening 102a is overlapped with the bottom opening 102b; that is, the top opening 102a is located at a position opposite to the bottom opening 102b. A difference between an aperture of the top opening 102a and an aperture of the bottom opening 102b is within 10 microns and for a through-hole which is formed by an ordinary mechanical drilling method, a difference between an aperture of an top opening and an aperture of a bottom opening is also about within 10 microns.

In the present embodiment, the insulation layer 120 can be a viscous material, such as a prepreg. In addition, the insulation layer 120 can include plural threads of a fiber material 122 and an adhesive material 124 which encloses these fiber materials 122. These fiber materials 122 can be fiber glass and the adhesive material 124 can be a resin material, such as epoxy resin.

Accordingly, as the through-holes 102 are formed by ablation with the laser beam, that is, the through-holes 102 are formed by using the laser beam to heat up, melt and vaporize part of the insulation layer 120; hence, the surfaces of the walls S1, i.e., the surfaces of the insulation layer 120 at the through-holes 102, will manifest an appearance like melted glass. Therefore, these fiber materials 122 are provided respectively with plural fused ends 122a.

These fused ends 122a are exposed on the walls S1 and these through-holes 102 will expose out these fused ends 122a. As these through-holes 102 are formed by heating up, melting and vaporizing part of the insulation layer 120, the fused ends 122a of one thread of the fiber material 122 will be welded with the fused ends 122a of another thread of the fiber material 122. In other words, two neighboring fiber materials 122 will be combined with each other in a same through-hole 102.

For the through-hole which is formed by the ordinary mechanical drilling method to the prepreg, the surface of the wall thereof will manifest the appearance of fractured fiber glass and basically, any two neighboring fiber materials in a same through-hole are separated with each other without being combined together. As a result, by watching directly through naked eyes or inspecting with a simple optical instrument like a magnifier or a microscope, an ordinary person can easily identify between the through-holes 102 that are formed by ablation with the laser beam and the through-holes that are formed by the ordinary mechanical drilling method.

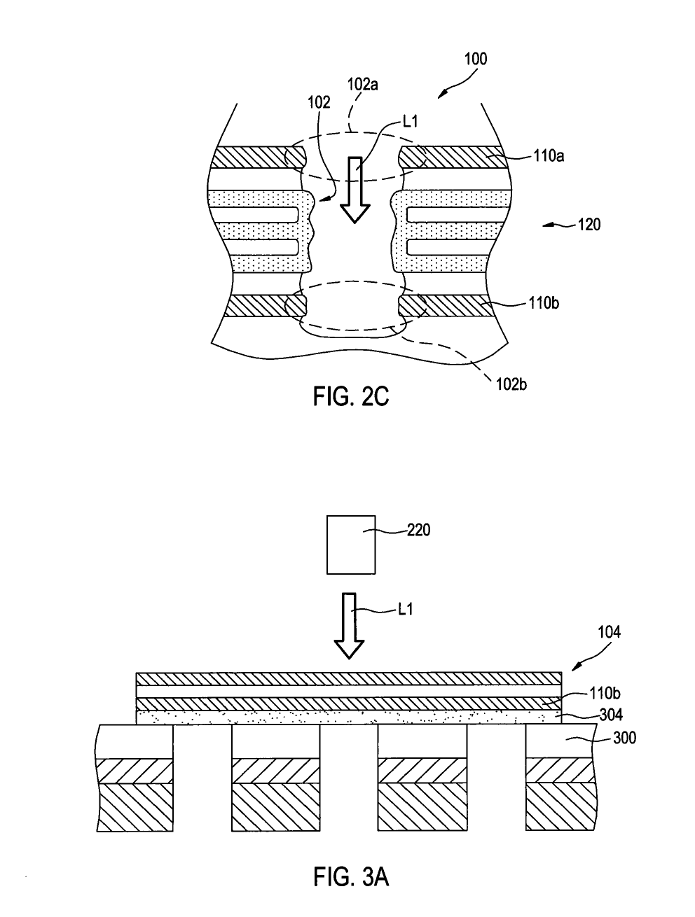

FIGS. 2A to 2C show flow diagrams of a drilling method for the substrate of the wiring board, as shown in FIG. 1A. As shown in FIG. 2A, regarding the drilling method of the present embodiment, first, a laser drill table 200 is provided. The laser drill table 200 is provided with a desk plate 210 and a laser generator 220, wherein the laser generator 220 can be a carbon dioxide laser device, an ultraviolet laser device or an excimer laser apparatus.

The desk plate 210 can be a single-layered board material or a complex board material including a multi-layered structure. For example, when the desk plate 210 is a complex board material, the desk plate 210 can include a first metal plate 212 and a second metal plate 214 which is configured on the first metal plate 212. On the other hand, the desk plate 210 can be provided with plural vacuum absorption holes 210a which are all perforations formed by penetrating the first metal plate 212 and the second metal plate 214.

Next, a laser absorption plate 300 is configured on the desk plate 210, wherein the laser absorption plate 300 can be fixed on the desk plate 210, such as by adhering or locking. The laser absorption plate 300 is provided with plural perforations 302 and these perforations 302 correspond respectively to the vacuum absorption holes 210a; that is, the perforations 302 are connected respectively with the vacuum absorption holes 210a.

As shown in FIG. 2B, next, a board material 104 is configured on the laser absorption plate 300, wherein the board material 104 can be a substrate of copper foil or an insulation layer, a surface of which has been already deposited with a metal layer. In addition, the board material 104 includes the upper conductive layer 110a, the lower conductive layer 110b and the insulation layer 120 which is configured between the upper conductive layer 110a and the lower conductive layer 110b. On the other hand, in other embodiments which are not shown in drawings, the board material 104 can further include a metallic core layer in the insulation layer 120.

When the board material 104 is configured on the laser absorption plate 300, the board material 104 will be temporarily fixed on the laser absorption plate 300, through vacuum adsorption, locking or clipping by a clamp, etc. For example, as the desk plate 210 is provided with the vacuum absorption holes 210a and the laser absorption plate 300 is provided with the perforations 302 which are connected with these vacuum absorption holes 210a, a vacuum pump (not shown in the drawings) which is provided by the laser drill table 200 can be used to adsorb the board material 104 from the vacuum absorption holes 210a and the perforations 302. Thus, the board material 104 can be temporarily fixed on the laser absorption plate 300.

Referring to FIG. 2B and FIG. 2C, after configuring the board material 104 on the laser absorption plate 300, the laser generator 220 will emit a laser beam L1 toward the desk plate 210 and irradiate the laser beam L1 on the board material 104 to form at least one through-hole 102 in the board material 104.

In details, when the laser beam L1 is irradiated on the board material 104, the laser beam L1 will heat up the board material 104 locally to ablate the board material 104. Accordingly, the upper conductive layer 110a, the lower conductive layer 110b and the insulation layer 120 will be heated up locally by the laser beam L1 and part of them will be melted and vaporized, thereby forming the through-holes 102. After forming the through-holes 102, a kind of substrate 100 of the wiring board is basically manufactured.

The laser absorption plate 300 can absorb the laser beam L1 and during the process that the laser beam L1 ablates the board material 104, the laser beam L1 will also ablate the laser absorption plate 300 underneath the board material 104. As the laser generator 220 can be a carbon dioxide laser device, an ultraviolet laser device or an excimer laser apparatus, the wavelength of the laser beam L1 can be between 200 nm and 14000 nm, and an absorption rate of the laser absorption plate 300 to light with the wavelength between 200 nm and 14000 nm is larger than 80%. As a result, the laser beam L1 can be effectively absorbed by the laser absorption plate 300, thereby ablating the laser absorption plate 300.

Accordingly, the laser absorption plate 300 can be made by a polymer material such as polymethylmethacrylate (acryl), epoxy resin or polytetrafluoroethylene (Teflon), or wood, pulp or ceramic which can effectively absorb the laser beam L1.

When the laser beam L1 ablates the board material 104 to form the through-holes 102, as the laser absorption plate 300 can effectively absorb the laser beam L1, the laser beam L1 will not be reflected easily by the laser absorption plate 300; hence, the lower conductive layer 110b is not easy to be damaged by the reflected laser beam L1, thereby improving circuit reliability of the wiring board.

As the laser beam L1 can be effectively absorbed by the laser absorption plate 300 to ablate the laser absorption plate 300, adjusting a parameter of the laser beam L1, such as a depth of field, will diminish the difference between the aperture of the top opening 102a and the aperture of the bottom opening 102b. In the present embodiment, this difference can be controlled to be within 10 microns.

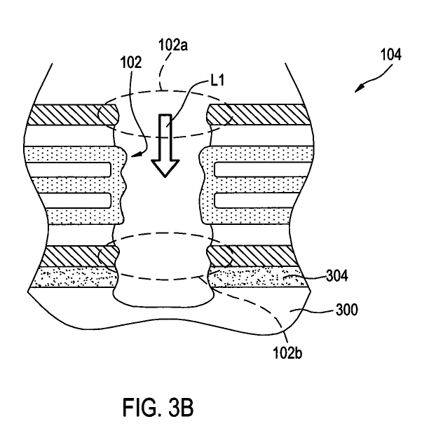

FIGS. 3A and 3B show flow diagrams of a drilling method for a substrate of a wiring board, according to an embodiment of the present invention. As shown in FIG. 3A, the drilling method of the present embodiment is similar to the drilling method shown in FIGS. 2A to 2C. The only difference is that in the drilling method of the present embodiment, before configuring the board material 104 on the laser absorption plate 300, a laser absorption film layer 304 will be formed on the board material 104.

Specifically, the laser absorption film layer 304 is formed on the lower conductive layer 110b, hence, when the board material 104 is configured on the laser absorption plate 300, the laser absorption film layer 304 will be located between the board material 104 and the laser absorption plate 300. There are a lot of methods to form the laser absorption film layer 304 and in the present embodiment; the laser absorption film layer 304 is formed by attaching a dry film on the board material 104. Therefore, the laser absorption film layer 304 can be a kind of dry film.

As shown in FIG. 3A and FIG. 3B, when the laser beam L1 which is emitted by the laser generator 220 ablates the board material 104 to form the through-holes 102, the laser absorption film layer 304 can also effectively absorb the laser beam L1, allowing the laser beam L1 not to be easily reflected by the laser absorption film layer 304 to protect the lower conductive layer 110b from being damaged by the reflected laser beam L1, thereby improving the circuit reliability of the wiring board.

On the other hand, during ablating the board material 104 by the laser beam L1, the laser beam L1 can also ablate the laser absorption film layer 304 and the laser absorption plate 300. In the present embodiment, through adjusting the parameter of the laser beam L1, such as the depth of field, the difference between the aperture of the top opening 102a and the aperture of the bottom opening 102b can be diminished and can be controlled to be within 10 microns, as well.

Concluding from the above, the present invention utilizes the laser beam to ablate the board material to form at least one through-hole on the board material, and at a same time, to form the substrate of the wiring board. The through-holes can be made into the conductive through-hole structure or the conductive buried-hole structure, to serve as electric connection among multiple circuit layers in the wiring board.

Next, as the present invention utilizes the laser beam to ablate to form the through-holes, the apertures of the through-holes of the present invention can be easily controlled to be below 75 microns. Compared to the conventional mechanical drilling method for the through-holes, the drilling method of the present invention is provided with an advantage of a low cost and is better in compliance with a trend of development toward a high wiring density of the existing wiring board.

Furthermore, the present invention utilizes the laser absorption plate or the laser absorption film layer which is able to absorb the laser beam and does not reflect the laser beam easily. Therefore, the drilling method of the present invention can protect the conductive layer (such as the lower conductive layer) of the board material from being damaged by the reflected laser beam, thereby improving the circuit reliability of the wiring board.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A substrate of a wiring board, being provided with at least one through-hole and comprising:
an upper conductive layer;
a lower conductive layer which is opposite to the upper conductive layer; and
an insulation layer which is configured between the upper conductive layer and the lower conductive layer, wherein the through-hole is formed by penetrating the upper conductive layer, the insulation layer and the lower conductive layer and is formed with a wall at the insulation layer, with a surface roughness of the wall being within 10 microns.

2. The substrate of a wiring board according to claim 1, wherein the through-hole is formed by ablation with a laser beam.

3. The substrate of a wiring board according to claim 1, wherein an aperture of the through-hole is below 75 microns.

4. The substrate of a wiring board according to claim 1, wherein the insulation layer is a prepreg.

5. The substrate of a wiring board according to claim 1, wherein the insulation layer includes plural threads of a fiber material.

6. The substrate of a wiring board according to claim 5, wherein the fiber materials are provided respectively with plural fused ends which are exposed on the wall, with the fused ends of one thread of the fiber material being welded with the fused ends of another thread of the fiber material.

7. The substrate of a wiring board according to claim 5, wherein the fiber materials are fiber glass.

8. The substrate of a wiring board according to claim 5, wherein the insulation layer further includes an adhesive material which encloses the fiber materials.

9. The substrate of a wiring board according to claim 8, wherein the adhesive material is resin.

10. The substrate of a wiring board according to claim 1, wherein the through-hole is further provided with an top opening at the upper conductive layer and a bottom opening at the lower conductive layer, with the top opening being overlapped with the bottom opening.

11. The substrate of a wiring board according to claim 10, wherein a difference between an aperture of the top opening and an aperture of the bottom opening is within 10 microns.

12. A drilling method for a substrate of a wiring board, comprising:
providing a laser drill table which includes a desk plate and a laser generator, with the laser generator emitting a laser beam toward the desk plate;
configuring a laser absorption plate on the desk plate;
configuring a board material on the laser absorption plate; and
irradiating the laser beam on the board material to form in the board material at least one through-hole.

13. The drilling method for a substrate of a wiring board according to claim 12, wherein an absorption rate of the laser absorption plate to light with a wavelength between 200 nm and 14000 nm is larger than 80%.

14. The drilling method for a substrate of a wiring board according to claim 12, wherein the laser absorption plate is made by polymethylmethacrylate, epoxy resin, polytetrafluoroethylene, wood, pulp or ceramic.

15. The drilling method for a substrate of a wiring board according to claim 12, wherein before configuring the board material on the laser absorption plate, the drilling method further includes forming a laser absorption film layer on the board material, such that when the board material is configured on the laser absorption plate, the laser absorption film layer is located between the board material and the laser absorption plate.

16. The drilling method for a substrate of a wiring board according to claim 15, wherein the method for forming the laser absorption film layer includes attaching a dry film on the board material.

17. The drilling method for a substrate of a wiring board according to claim 12, wherein the laser generator is a carbon dioxide laser device, an ultraviolet laser device or an excimer laser apparatus.

18. The drilling method for a substrate of a wiring board according to claim 12, wherein upon configuring the board material on the laser absorption plate, the laser drill table adsorbs the board material from the desk plate.

19. The drilling method for a substrate of a wiring board according to claim 18, wherein the desk plate is provided with plural vacuum absorption holes and the laser absorption plate is provided with plural perforations which are connected with the vacuum absorption holes.

20. The drilling method for a substrate of a wiring board according to claim 12, wherein the desk plate includes a first metal plate and a second metal plate which is configured on the first metal plate.
